(19) United States
(12) Patent Application Publication
(10) Pub. No.: US 2016/0218257 A1
(43) Pub. Date: Jul. 28, 2016

(54) PRINTED LED LIGHT SHEETS WITH REDUCED VISIBILITY OF PHOSPHOR LAYER IN OFF STATE

(71) Applicant: Nthdegree Technologies Worldwide Inc., Tempe, AZ (US)

(72) Inventors: William J. Ray, Fountain Hills, AZ (US); Reuben Rettke, Phoenix, AZ (US); Mark D. Lowenthal, Vancouver, WA (US); Jeffrey Baldridge, Chandler, AZ (US)

(21) Appl. No.: 15/008,383

(22) Filed: Jan. 27, 2016

Related U.S. Application Data
(60) Provisional application No. 62/108,900, filed on Jan. 28, 2015.
(60) Provisional application No. 62/108,815, filed on Jan. 28, 2015.
(60) Provisional application No. 62/108,875, filed on Jan. 28, 2015.
(60) Provisional application No. 62/109,863, filed on Jan. 30, 2015.
(60) Provisional application No. 62/117,070, filed on Feb. 17, 2015.
(60) Provisional application No. 62/207,837, filed on Aug. 20, 2015.
(60) Provisional application No. 62/215,869, filed on Sep. 9, 2015.
(60) Provisional application No. 62/242,239, filed on Oct. 15, 2015.

(51) Int. Cl. H01L 33/50; H01L 33/08

(52) U.S. Cl. CPC H01L 33/505; H01L 33/08

(57) ABSTRACT

Various applications and customizations of a thin flexible LED light sheet are described. Microscopic LED dice are printed on a thin substrate, and the LEDs are sandwiched between two conductor layers to connect the LEDs in parallel. The conductor layer on the light emitting side is transparent. In one embodiment, small dots of printed blue LED dies with overlapping dots of a YAG (yellow) phosphor are formed on a substrate, with the areas between the dots being a neutral color or an anti-color (blue for a yellow phosphor).

The LED dies are connected in parallel. When the LED dies are in their off state, the yellow phosphor dots will not be perceived by human eyesight at typical viewing distances, and the overall resulting color will be either a pleasing off-white color or a neutral color. The lamp will appear white when the LED dies are on.

### CROSS-REFERENCE TO RELATED APPLICATIONS

This application claims the benefit of the following U.S. Provisional Application Ser. Nos. 62/108,900, filed on Jan. 28, 2015; 62/108,815, filed on Jan. 28, 2015; 62/108,875, filed on Jan. 28, 2015; 62/109,863, filed on Jan. 30, 2015; 62/117,070, filed on Feb. 17, 2015; 62/207,837, filed on Aug. 9, 2015; 62/215,869, filed on Sep. 9, 2015; and 62/242,239, filed on Oct. 15, 2015, all applications being assigned to the present assignee and incorporated by reference.

### FIELD OF THE INVENTION

This invention relates to flexible sheets of printed microscopic inorganic light emitting diodes (LEDs) and, in particular, to various applications of such sheets.

### BACKGROUND

Applicant had previously invented a technique for printing microscopic LED dies on a flexible substrate to form a very thin LED sheet of any size and shape. This is described in the assignee's U.S. Pat. No. 8,852,467, incorporated herein by reference.

What is needed is the invention of a wide variety of marketable applications based on this basic LED light sheet.

### SUMMARY

Various applications and customizations of a thin flexible LED light sheet are described. Microscopic LED dice are printed on a thin substrate, and the LEDs are sandwiched between two conductor layers to connect the LEDs in parallel. The conductor layer on the light emitting side is transparent.

In one embodiment, small dots of printed blue LED dies with overlapping dots of a YAG (yellow) phosphor are formed on a substrate, with the areas between the dots being a neutral color or an anti-color (blue for a yellow phosphor). The LED dies are connected in parallel. When the LED dies are in their off state, the yellow phosphor dots will not be perceived by human eyesight at typical viewing distances, and the overall resulting color will be either a pleasing off-white color or a neutral color. The lamp will appear white when the LED dies are on.

### BRIEF DESCRIPTION OF THE DRAWINGS

FIG. 1 is a cross-sectional view of a small portion of a printed LED light sheet that has been customized for any of the applications described herein.

FIG. 2 is a top down view of the LED light sheet of FIG. 1 where FIG. 1 is taken along the line 1-1 in FIG. 2.

FIG. 3 is a perspective view of a product shelf having an angled LED light strip near the front edge of the shelf illuminating products on the shelf.

FIGS. 4-10 illustrate variations of the LED light strip shown in FIG. 3 along the front edge of the shelf that achieve additional benefits.

FIG. 11 illustrates a translucent or transparent front panel backlit by a spaced back panel containing printed LED dies.

FIG. 12 illustrates a translucent or transparent front panel backlit by a back panel, in direct contact with the front panel, containing printed LED dies.

FIG. 13 illustrates a transparent light guide substrate edge lit by an LED light strip, where the light guide substrate may act as a backlight or convey information using light extraction features.

FIG. 14 illustrates a light guide substrate with a random pattern of light extraction features for conveying information or for emitting a substantially uniform backlight.

FIG. 15 illustrates a light guide substrate with a random pattern of variable size light extraction features, for further randomizing and mixing light, for conveying information or for emitting a substantially uniform backlight.

FIG. 16 illustrates a light guide substrate with a pattern of light extraction features that convey information, such as alpha-numeric characters.

FIG. 17 illustrates a 3-dimensional light guide containing a 3-dimensional LED light sheet for backlighting or for conveying information using light extraction features on its outer surface.

FIG. 18 illustrates a backlit cover sheet containing graphics (such as fluorescent paint) or light extraction features, wherein a memory IC controls an addressable LED light sheet used as a backlight.

FIG. 19 illustrates an edge lit light guide having graphics (such as fluorescent paint) printed on its surface.

FIG. 20A illustrates the front of a transparent substrate having printed on it electronic circuitry, such as touch sensors and transistors, and graphics (e.g., keypad numbers) that may be used as a control panel touched by a user.

FIG. 20B illustrates the back of the substrate of FIG. 20A, where an LED light sheet backlights the control panel formed on the front surface.

FIG. 21 illustrates a flat, curved LED light sheet that may be sewn on clothing, where an array of identical LED light sheets may be interconnected in parallel by overlapping anode and cathode landing pads.

FIG. 22 is similar to FIG. 21 but shows multiple addressable LED sections.

FIG. 23 is an exploded view illustrating one embodiment of a technique for securing the LED light sheets of FIG. 21 to clothing and connecting them together in parallel.

FIG. 24 illustrates how the LED light sheet of FIG. 21 may be affixed to an inner surface of clothing if the clothing material allows sufficient light to pass through.

FIG. 25A is a front view of a lamp where printed dots of cured LED ink underlie printed dots of a yellow YAG phosphor, and the area surrounding each dot is either a neutral color or an anti-color (e.g., blue) so that the lamp appears generally white to an observer at a sufficient distance when the LEDs are off. The LEDs in all the dots are connected in parallel by being sandwiched between conductive layers.

FIG. 25B is a magnified portion of the lamp of FIG. 25A.

FIG. 26 illustrates the lamp of FIG. 25 without metal bus bars and horizontal metal runners used for distributing current over the LED light sheet.

FIG. 27 is a cross-sectional view of the lamp of FIG. 25.

FIG. 28 illustrates a large light panel, such as a 2 foot×4 foot troffer, where the LED dots and phosphor dots (e.g., yellow YAG) are surrounded by an anti-color, such as blue, and where the areas of the yellow and blue are approximately the same to create white light under ambient light when the LEDs are off.

FIG. 29 illustrates a roll-to-roll process, under atmospheric conditions, that can be used to create all the LED light sheets described herein.

FIGS. 30-33 illustrate various patterns of two types of LEDs that emit different wavelengths.

FIG. 34 illustrates an optical sensor that has an array of RGB filters over an array of printed photodiodes to detect images, colors, etc.

FIG. 35 is a cross-sectional view of a small portion of the system of FIG. 34.

Elements that are the same or similar are labeled with the same numeral.

### DETAILED DESCRIPTION

### General Description of LED Light Sheets that may be Customized for Each Application

The present assignee has previously invented a flexible light sheet formed by printing microscopic inorganic (GaN) vertical LED dice over a conductor layer on a flexible substrate film to electrically contact the LED's bottom electrodes, then printing a thin dielectric layer over the conductor layer which exposes the LED's top electrodes, then printing another conductor layer to contact the LED's top electrodes to connect them in parallel. Either or both conductor layers may be transparent to allow the LED light to pass through. The LEDs may be printed to have a large percentage of the LEDs with the same orientation so the light sheet may be driven with a DC voltage. The LEDs may also be printed with a random orientation and driven with an AC voltage. The light sheet may have a thickness between 5-13 mils, which is on the order of the thickness of a sheet of paper or cloth. This is described in the assignee's U.S. Pat. No. 8,852,467, entitled, Method of Manufacturing a Printable Composition of Liquid or Gel Suspension of Diodes, incorporated herein by reference.

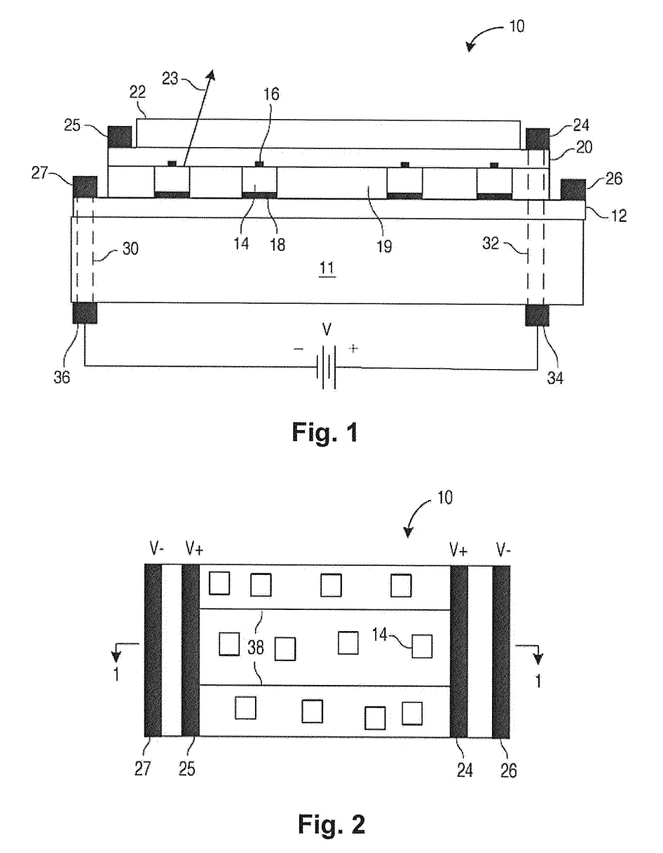

FIGS. 1 and 2 illustrate a small portion of such a light sheet 10 that has been customized for use in any of the embodiments described herein, such as by customizing its shape, or size, or density of LEDs, or color of LEDs, or control of the LEDs, or pattern of the LEDs, or other characteristics.

In FIG. 1, a starting substrate 11 may be any stable material that can withstand the high temperature curing temperatures during the processing. Such materials may include polycarbonate, PET (polyester), PMMA, Mylar or other type of polymer sheet, a thin metal film (e.g., aluminum), paper, cloth, or other material. In one embodiment, the substrate 11 is about 25-50 microns thick.

A conductor layer 12 is then deposited over the substrate 11, such as by printing. The substrate 11 and/or conductor layer 12 may be reflective or transparent.

The conductor layer 12 may be patterned to form pixel locations for selectively addressing LEDs within each pixel area.

A monolayer of microscopic inorganic LEDs 14 is then printed over the conductor layer 12. The LEDs 14 are vertical LEDs and include standard semiconductor GaN layers, including an n-layer, and active layer, and a p-layer. GaN LEDs typically emit blue light. The LEDs 14, however, may be any type of LED emitting red, green, yellow, infrared, ultraviolet, or other color light.

In one embodiment, the LEDs 14 have a diameter less than 50 microns and a height less than 10 microns. The number of micro-LED devices per unit area may be freely adjusted when applying the micro-LEDs to the substrate 11. A well dispersed random distribution across the surface can produce nearly any desirable surface brightness. The LEDs may be printed as an ink using screen printing, flexography, or other forms of printing. Further detail of forming a light source by printing microscopic vertical LEDs, and controlling their orientation on a substrate, can be found in the assignee's U.S. Pat. No. 8,852,467.

The orientation of the LEDs 14 can be controlled by providing a relatively tall top electrode 16 (e.g., the anode electrode), so that the top electrode 16 orients upward by taking the fluid path of least resistance through the solvent after printing. The anode and cathode surfaces may be opposite to those shown. The LED ink is heated (cured) to evaporate the solvent. After curing, the LEDs remain attached to the underlying conductor layer 12 with a small amount of residual resin that was dissolved in the LED ink as a viscosity modifier. The adhesive properties of the resin and the decrease in volume of resin underneath the LEDs 14 during curing press the bottom cathode electrode 18 against the underlying conductor layer 12, creating a good electrical connection. Over 90% like orientation has been achieved, although satisfactory performance may be achieved with over 75% of the LEDs being in the same orientation.

A transparent polymer dielectric layer 19 is then selectively printed over the conductor layer 12 to encapsulate the sides of the LEDs 14 and further secure them in position. The ink used to form the dielectric layer 19 pulls back from the upper surface of the LEDs 14, or de-wets from the top of the LEDs 14, during curing to expose the top electrodes 16. If any dielectric remains over the LEDs 14, a blanket etch step may be performed to expose the top electrodes 16.

A transparent conductor layer 20 is then printed to contact the top electrodes 16. The conductor layer 20 is cured by lamps to create good electrical contact to the electrodes 16. The transparent conductor layer 20 may be patterned to form addressable locations (e.g., pixels) for selectively addressing LEDs within each location.

The LEDs 14 in the monolayer, within each addressable location, are connected in parallel by the conductor layers 12/20 since the LEDs 14 have the same orientation. Since the LEDs 14 are connected in parallel, the driving voltage will be approximately equal to the voltage drop of a single LED 14.

A flexible, polymer protective layer 22 may be printed over the transparent conductor layer 20. If wavelength conversion is desired, a phosphor layer may be printed over the surface, or the layer 22 may represent a phosphor layer. The phosphor layer may comprise phosphor powder (e.g. a YAG phosphor) in a transparent flexible binder, such as a resin or silicone. Some of the blue LED light leaks through the phosphor layer and combines with the phosphor layer emission to produce, for example, white light. A blue light ray 23 is shown.

The flexible light sheet 10 of FIG. 1 may be any size and may even be a continuous sheet formed during a roll-to-roll process that is later stamped out for a particular application.

FIGS. 1 and 2 also illustrate how the thin conductor layers 12 and 20 in a single pixel area on the light sheet 10 may be electrically contacted along their edges by metal bus bars 24-27 that are printed and cured to electrically contact the conductor layers 12 and 20. The metal bus bars along opposite edges are shorted together by a printed metal portion outside of the cross-section. The structure may have one or more conductive vias 30 and 32 (metal filled through-holes), which form a bottom anode lead 34 and a bottom cathode lead 36 so that all electrical connections may be made from the bottom of the substrate 11. A suitable voltage differential applied to the leads 34 and 36 turns on the LEDs 14 to emit light through one or both surfaces of the light sheet 10. The metal bus bars 24-27 may form row and column addressing lines for lighting up only those LEDs within at the intersection of energized row and column lines. Each pixel location can be any size, depending on the desired resolution.

FIG. 2 is a top down view of the light sheet 10 of FIG. 1, where FIG. 1 is taken along line 1-1 in FIG. 2. If there is a significant IR drop across the transparent conductor layer 20, thin metal runners 38 may be printed along the surface of the conductor layer 20 between the opposing bus bars 24 and 25 to cause the conductor layer 20 to have a more uniform voltage, resulting in more uniform current spreading. In an actual embodiment, there may be thousands of LEDs 14 in a light sheet 10.

The following applications of the assignee's LED light sheet may use customized versions of the LED light sheet of FIGS. 1 and 2 that are optimized for the particular application.

### Method to Front-Illuminate Objects Placed Upon a Shelf—(NTH-LIGT-0814-0176)

A technique is described that provides front, bottom-up illumination of an object placed upon a shelf such as a retail store's shelf. The microLED footlight device is thin, efficient and can provide numerous color shades to optimize such illumination.

Conventional vertically stacked shelving supporting commercial products frequently use top down lighting, where lamps are affixed to the bottom of a shelf for illuminating products on the underlying shelf. This is similar to under-cabinet lighting for kitchens. Such top down lighting will often cast a shadow upon the front facing side of the products or goods displayed. This shadow burdens the customer as it can make it difficult to both read the front facing label and to find the brand or product type that the customer is looking for.

Retail stores appear to always be short of shelf space, given the number of competing products, and stocking is almost universally done in such a way as to pull the products to the edge of the shelf. Further, shelf height is generally adjusted to the minimum reasonable clearance from the top of the respective products to the bottom of the next shelf up. This step maximizes the number of shelves easily accessible to the consumer. This results in even worse lighting of the products with the conventional top down lighting.

The solution to these lighting problems is placement of the light on the top front lip of the shelf where the merchandise or object to be illuminated will be placed, much in the same way a footlight is used for stage lighting.

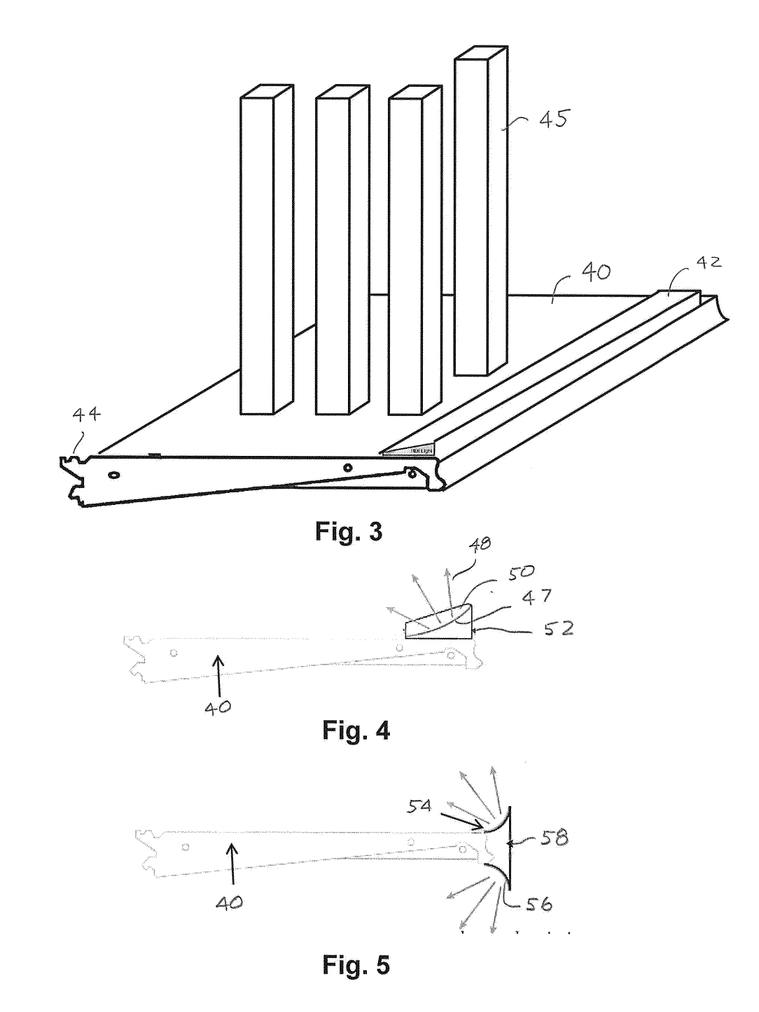

FIG. 3 shows an adjustable-height metal shelf 40 with an angled LED light strip 42 along its front edge, similar to a footlight. The back edge 44 of the metal shelf forms a narrow securing mechanism that fits into a slot, in a column of slots, in a fixed vertical support. The other end of the shelf 40 has a similar securing mechanism. A product 45 is shown being illuminated by the LED light strip 42.

The footlight apparatus of FIG. 3 may consist of number of different lighting source types. Such light sources are attached to the outward top edge of the shelf 40. A preferred embodiment uses printed microLED strips, such as shown in FIGS. 1 and 2. A very slight elevation of the footlight is preferred but not required in the case of the printed microLEDs as such devices are Lambertian light emitters and, as such, will broadly illuminate the front of the product placed on the shelf. Further, using printed microLEDs produces a diffuse area light with little glare for the observer. The light impinges on at least the entire front surfaces of the products in the front row of the shelf, and there will be virtually no shadows.

The LED light strips in the various embodiments may be affixed to the front of the shelves with a removable adhesive, or magnetically, or placed within a slot, or other affixing technique.

Those skilled in the art have numerous design options using microLED strips. Several of these options are illustrated in FIGS. 4-10.

FIG. 4 illustrates the shelf 40 with an LED light strip 47 that is curved upward to provide a more efficient emission profile, where more light is directed toward the product on the shelf 40 rather than illuminating the bottom of the overlying shelf. In other words, more light is directed at a lower angle compared with the light emission of the LED light strip 42 in FIG. 3. Light rays 48 at different angles are shown. The lower area of the light strip 47 has a slight upward angle while the upper area of the light strip 47 has a much larger upward angle for directing more light directly toward the product. The curved light source more uniformly illuminates the product surface. FIG. 4 also illustrates an optional diffuser 50 over the light strip 47. A vertical flat area 52 of the LED light strip support structure may be used for advertising, such as graphics that are temporarily affixed to the flat area, or erasable, which identify the product and/or the price. The flat area 52 may also be a programmable display using an array of printed LEDs.

FIG. 5 illustrates the shelf 40 with a first LED light strip 54 that is curved upward to provide a more efficient emission profile, where more light is directed toward the product on the shelf 40 and where the light more uniformly illuminates the product, compared with the light emission of the LED light strip 42 in FIG. 3. A curved second LED light strip 56 directs light on the fronts of the products in the front row of the underlying shelf. Therefore, products are illuminated more uniformly due to the top and bottom illumination. Each shelf, except the topmost and bottommost shelf, will have the up and down facing LED light strips 54/56. The curves of the LED light strips 54/56 may be different due to the different distances between the products to be illuminated and the respective LED light strips 54/56. For example, the bottom LED light strip 56 may be less curved since the lower products are further away. A flat area 58 between the LED light strips may be used for advertising, as described with respect to FIG. 4.

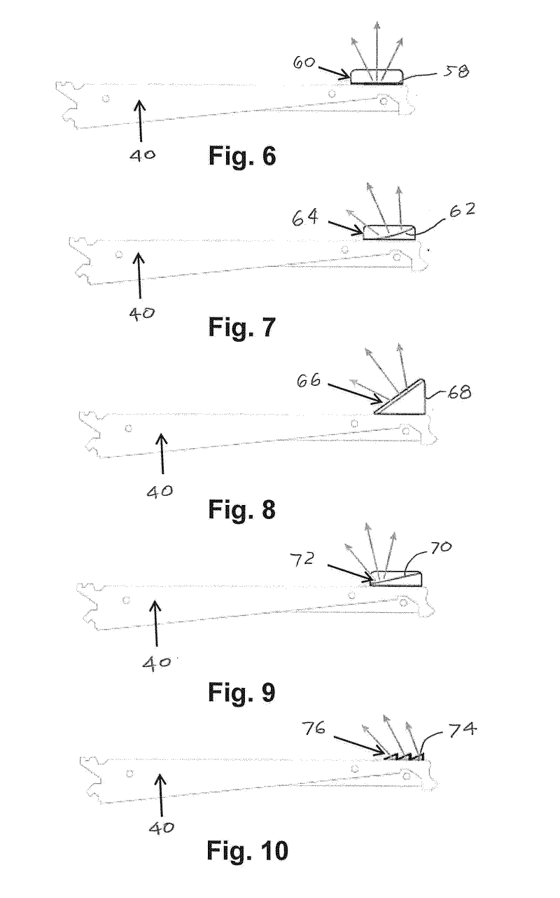

FIG. 6 illustrates an LED light strip 58, where a diffuser 60 or lens array directs the light toward the product and reduces glare.

FIG. 7 illustrates a LED light strip 62 with a curved surface, where a diffuser 64 or lens array directs the light toward the product and reduces glare.

FIG. 8 illustrates a LED light strip 66 with an angled flat surface. A flat area 68 provides an advertising area, which may be a programmable display using an array of printed LEDs.

FIG. 9 illustrates a LED light strip 70 with an angled flat surface, where a diffuser 72 or lens array directs the light toward the product and reduces glare.

FIG. 10 illustrates a LED light strip 74 with a flat surface, where a prismatic diffuser or reflector 76 directs the light toward the product and reduces glare.

Power to the various LED light strips may be by a wire or traces that terminate in a connector that attaches to a power source bus running along the back vertical wall of the shelf support.

### Various Applications for Backlights—(NTH-LIGT-0115-0187)

Backlighting is a known need for such consumer products as addressable displays, static advertising, esthetic products (such as architectural lighting) and other many other forms of consumer products. The below description deals with some of the large number of novel devices that can be built or enhanced by using printed microLED devices enabled by the asssignee's random diode ink to a substrate of any sort.

Several device structures for backlighting can be conceived of. Examples of some possible designs are illustrated in FIGS. 11-17.

Indirect, remote backlighting is illustrated in FIG. 11. In this example, the back, illuminating panel 80 is a microLED light sheet and is offset from a front panel 82 at such a distance as to diffuse/mix the intense points of light of the randomly-distributed LED dies in the panel 80. The front panel 82 may consist of any graphic display type or addressable display type that is transparent, translucent, semi-opaque, di-chromatic, electro-chromatic or other permanent or transient or addressable image that blocks, converts, shifts or filters light.

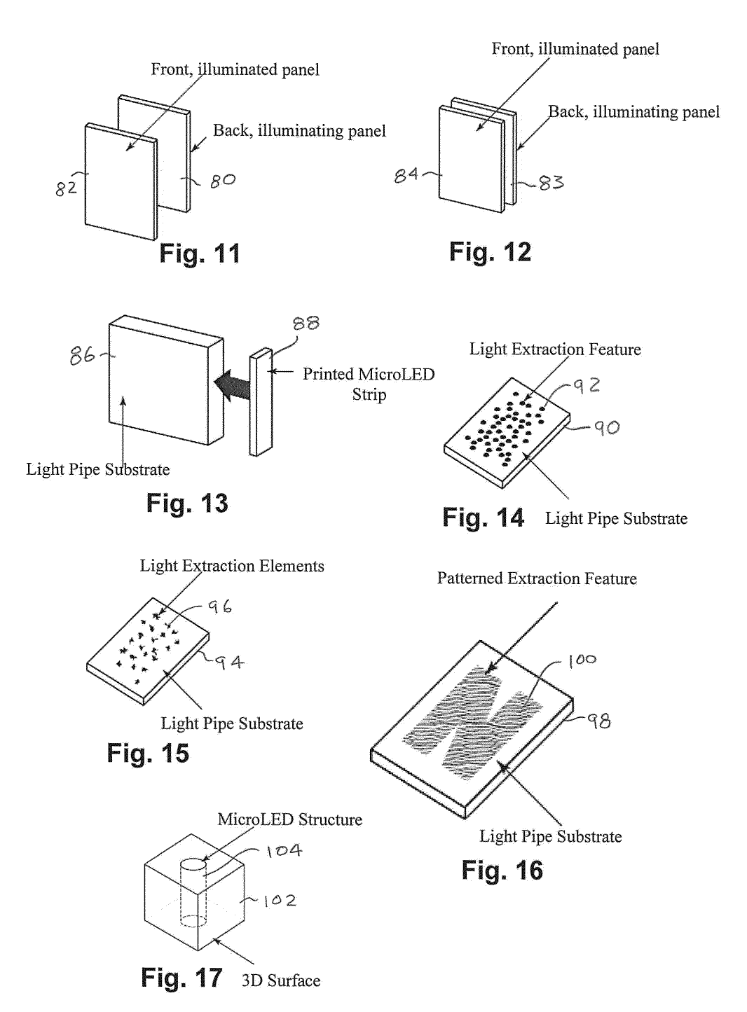

Direct, intimate backlighting is illustrated in FIG. 12. Direct backlighting provides little or no diffusion of the microLED random array in the back panel 83. The array of LED dies may be printed in discrete areas of random LED dies, yielding a closely packed random array for such areas. The front panel 84 may consist of any graphic display type or addressable display type that is transparent, translucent, semi-opaque, di-chromatic, electro-chromatic or other permanent or transient or addressable image that blocks, converts, shifts or filters light. The level of intimate contact may vary. Direct attachment of the panels 83 and 84 may be used for a very thin and flexible display, or an intervening substrate layer may be present (illustrated by the small gap in FIG. 12). Such an intervening layer may contain optically active materials of many types, including phosphors, or may just be an air gap.

Edge lighting is illustrated in FIG. 13. A waveguide (or light pipe) substrate 86 may consist of any material that is transparent, translucent, or semi-opaque. One preferred material is a clear polymer layer that leaks light out its front surface, although many other materials can be used. The front surface of the substrate 86 includes graphics that are highlighted by the light leaking out the front of surface of the substrate 86, or the substrate 86 backlights another panel having graphics. The printed microLED strip 88 may be of any size or shape consistent with the edge width of the substrate 86. The microLED strip 88 is applied to one or more edges of the substrate 86 depending upon the particular design required.

FIGS. 14-16 illustrate various different devices that can be built from the basic light pipe approach of FIG. 13. Light will pass through the planar surface of the light pipe substrate 90 effectively from edge to edge. If the material used as the light pipe substrate 90 intrinsically exhibits diffusing characteristics, the light pipe substrate 90 will glow to one extent or another, depending upon the amount of diffusion that results. Applying features of various types to the planar surface of the light pipe substrate 90 will extract light preferentially to the type, number, and density of those features.

FIG. 14 illustrates a random additive application of such light extraction elements 92, to generate a substantially uniform backlight. In another embodiment, the light extraction elements 92 are in a particular pattern to directly convey information. Light extraction may be achieved by roughening, such as etching, or attaching optical materials such as micro to nano sized beads or irregular particles.

In one example, photonic structures may be used on the surface of the light pipe substrate 90 that are regular in feature, such as glass or polymer beads. The optical beads can provide more active optical effects than the irregular particles. Some instantiations of the optical bead approach include Mie scattering effects where light is extracted from the optical plane and “multiplied” by the Mie effect.

Another instantiation is the use of embedded florescence materials in polymer micro beads affixed to the surface of the light pipe substrate 90 in a desired pattern. This approach allows the optical plane to be patterned with different Stokes shifting materials that allow multiple emitting colors to be combined with whatever pattern may be printed graphically. The result is that a highly extra-trinary color space can be achieved using both additive and subtractive color. The beads may be affixed using an adhesive or by slightly melting the surface of the substrate 90.

FIG. 15 illustrates a light pipe substrate 94 having a pattern of irregularly shaped light extraction features 96 to increase the randomization of the light emission for better light uniformity.

FIG. 16 illustrates a light pipe substrate 98 having a surface with a patterned variant of both the additive and subtractive light extraction elements 100. In one example of FIG. 16, a roughened area in the shape of the letter N is achieved by masked etching. The light extraction elements 100 may instead be beads, phosphors, or other types. An additive approach may be applied to the same patterned area to create more complex graphics or colors using the materials defined above.

FIG. 17 illustrates a volume backlight 102. A volume backlight is a structure within a structure. In one example the inner, light source is a printed microLED sheet 104 that is either converted (e.g., folded, molded, or spindled) into the desired shape or is directly applied to a three dimensional object to obtain the shape required. The outer 3-dimensional structure may by a transparent polymer (or other suitable material) that is molded around the microLED sheet 104 or has an opening for receiving the microLED sheet 104. Although FIG. 17 illustrates a cube, the structure can have any shape, such as a sphere, pyramid, etc. The outer surface of the structure may include any pattern of light extraction elements.

The inner microLED sheet 104 may have some form of color conversion material applied to it, such as YAG phosphor, or may emit only the native LED output. The outer structure may have color conversion elements patterned or coated on it and/or may have reflective, filtering, or opaque materials applied on either the inner or outer surface.

Specific types of products using the backlights described above may include:
Backlit signs including instrument panels;
Addressable displays;
Entertainment (visual effects in theaters, photo studios, musical instruments);
Backlighting musical instruments such as keyboards for pianos or guitar surfaces, or backlighting keyboards for typing;
Household backlighting (of all types) may be used in picture frames and picture holders (3D);
Lighting hallways (e.g., backlit tiles), lighting around switch controls, key chains;
Table-top lighting pieces for top, side or under-coffee table application;
Utility lighting for energizing a device made with a storage phosphor that emits light for a period after the energizing light has been removed. The charged phosphor device could then be removed from charger and used as an independent light that does not require a power source. Alternately, LEDs could be embedded in a storage phosphor device. The device would continue to glow after LED power is turned off. This could extend the lifetime of a marker light (for example) beyond the capacity of the battery;
Utility lighting where an LED sheet and a battery are fully enclosed in a plastic float for use as a pool light. The battery can be recharged from an AC line or inductively;
Venetian blind lighting. When the blinds are closed (e.g., at night), they create an electrical circuit and light up. When they are open, the circuit is broken and they turn off. Magnets can be used to insure a good connection when the blinds are closed;
A 3-electrode circuit where one side is used to power a lamp and the other to power a dichromic device. When the lamp is off, the dichromic device is opaque (obscuring the lamp circuit and remote phosphor) and, when the lamp is on, the dichromic device is transmissive and allows the passage of light;
A mirror is half-silvered, or has regions that are half-silvered. An LED sheet is attached to the mirror where it is half-silvered, providing uniform light through the minor when wanted;
Interactive toys similar to etch-a-sketch using bright colors;
Lit-up Twister game sheet;
Illuminating toys or games for playing in the dark, or for graphics in such toys games;
Board games of all sorts;
Arcade games;
Dance game, stepping on the correct highlighted color;
An LED light and battery that are part of an inflatable structure that can be easily and quickly inflated for a variety of uses.

### Fluorescent Paint Electronic Display—(NTH-LIGT-0215-0189)

A blue emitting LED display with interchangeable cover sheets is described in which either a direct emitting style or an edge lit style backlight is used. The cover sheets may or may not have an image patterned on them prior to application. The sheets can be painted or printed upon using a fluorescent paint or ink to create very high contrast images.

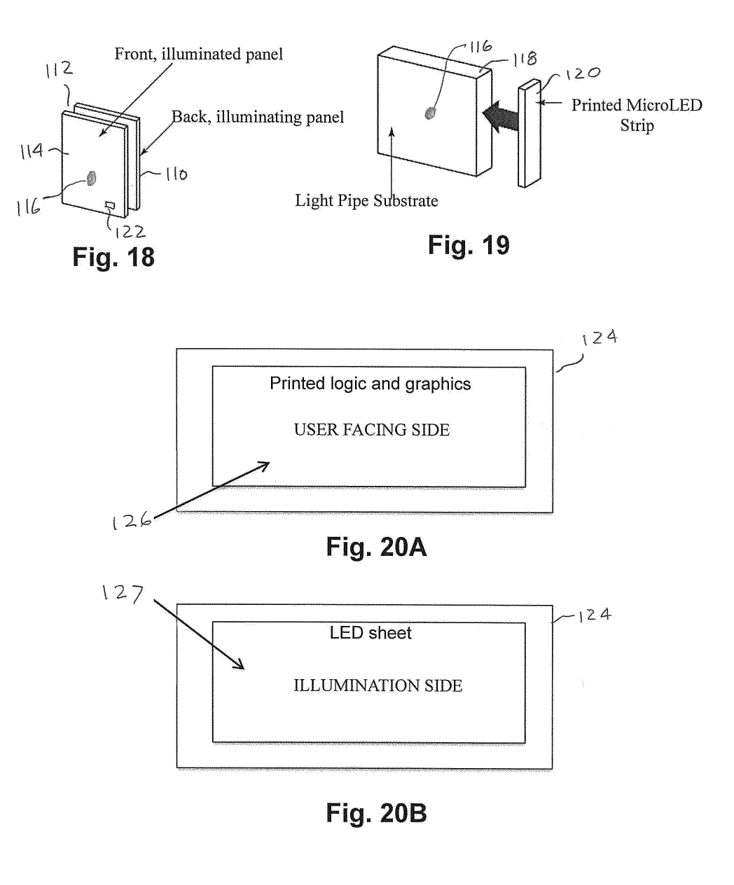

FIGS. 18 and 19 illustrate a device that allows a high contrast image to be patterned upon it. In its most simple form, the device uses a microLED backlight sheet emitting in the blue spectrum and a transparent or semi-opaque front substrate sheet that may be painted or printed upon. The light source must have enough uniformity to achieve an acceptable image. The basic backlighting structures of FIGS. 12 and 13 are employed in the embodiments of FIGS. 18 and 19 to illustrate the fluorescent paint feature.

Printed light sheets allow a novel solution to the problem of backlight uniformity. One such solution, shown in FIG. 18, is to use a sheet of printed microLEDs 110 (emitting UV or blue light), a sheet of intermediate diffusion material 112 or an air spacer, and a final cover sheet 114 on which is applied a fluorescent paint 116 in any pattern. The paint 116 is energized by the backlight and may be any color. Areas on the transparent cover sheet 114 that do not have the paint 116 on it internally reflect the light due to the large mismatch between the indices of refraction of the cover sheet 114 (e.g., a plastic film) and air, or the blue color contrasts with the fluorescent paint 116 color. The paint 116 material has a much higher index of refraction than air, so the light within the cover sheet 114 enters the paint 116 and energizes it to produce the desired color.

Another such solution is to use a sheet of printed LEDs adhered to a standoff sheet, with the paint 116 being applied to a sheet of diffusing material.

FIG. 19 shows an edge lit light pipe substrate 118 with an LED strip 120 (such as emitting UV or blue light) affixed to its edge. The fluorescent paint 116 causes light to escape the light pipe substrate 118 into the paint 116 to energize it to create any color and pattern. No light escapes other portions of the smooth surface of the light pipe substrate 118.

A non-edge lit device could employ addressable light features. Addressing regions of the LEDs within the printed light sheet allows the selection of lit areas. There are several ways to incorporate this feature. For instance, the cover sheet 114 of FIG. 18 could have a static image printed upon it along with having a memory IC 122 mounted on it. When the cover sheet memory is “connected” to the addressable light sheet, the cover sheet memory communicates with the light sheet addressing circuitry to identify what regions or patterns (pixel locations) to light up. For example, a USB connector may extend from the cover sheet and light sheet, and a power supply (e.g., a 9 volt battery) may supply all power. Therefore, the light sheet may be a standardized addressable light sheet, and the particular customized cover sheet (including the memory IC) defines the image generated. Animations are possible with this system by the memory IC identifying the sequence of LED regions to illuminate, and the illuminated regions backlighting suitable animation images printed on the cover sheet. Additionally, the memory IC on the cover sheets can be user-configured by connecting the cover sheet memory IC to a programming board or computer. This technique would allow the user to self-configure the addressed areas and provide a customized cover sheet. If the cover sheet contains touch sensors, the addressable LED light sheet can light up areas that are touched by the user. Paint patterns on the cover sheet may be numbers in a keypad or other icons.

Memory built into the cover sheet allows animations or selected areas to light only for that particular cover sheet. This allows the user to swap cover sheets and have the lit areas customized for each cover sheet. Built in memory can also be achieved by printing transistors and interconnect circuitry onto the cover sheet itself to form a logic circuit defining the addressing of the LED light sheet.

### Method to Build Lighted Panels that Allow Information Display and User Control of Electrical and Mechanical Devices—(NTH-LIGT-0815-0200)

Lighted panels are important tools for control of various machines and electrical devices. Historically, these devices are assembled from various electromechanical switches and other components that are attached through holes in a metal or plastic panel. Solid state panels have been employed for certain uses as well, however, it is common for these panels to be either fragile with long term use or to be environmentally compromised over time.

Disclosed below is a completely solid state control panel that is built using a statistical electronics approach and which includes simple solid state switching devices. In this context, a “statistical electronics approach” is the printing of transistors, LEDs, diodes, or other components in an array of small areas where each small area contains a random distribution of the same microscopic components connected in parallel by conductive layers. Thus, each predefined small area acts as a single component. The array of components can then be interconnected by traces, which may be programmable, to build a complex logic circuit, such as comprising interconnected logic gates, or to build an addressable LED display. The printing technique for printing transistors and other micro-components may be similar to the technique described with respect to FIG. 1.

The starting substrate may be a flat transparent material of a given X-Y dimension and an appropriate thickness (Z dimension) such that it is appropriate for a control or display panel of any sort. This layer may or may not be drilled with one or more through vias for subsequent filling with conductive materials.

For a control panel, on the user facing side, switch and control logic may be printed (using the statistical electronics approach) on the substrate along with subsequent graphic arts which may cover the circuit layers for esthetic reasons. The graphic arts may instead be a separate opaque layer with “knocked out” portions that pass light to display switch/control indicators.

On the opposite side of the substrate, the side away from the user, a sheet of microLEDs is applied as a backlight for either a control panel or a display panel. The microLED sheet may be printed directly on the substrate or laminated. The microLED sheet layer, or the LED pattern within the sheet, may be patterned to conform to the patterns printed on the user-facing side or may simply be a uniform microLED light sheet that fits within the panel dimensions. Accordingly, electronic controls, such as touch sensors and addressing circuits, may be integrated with the microLED light sheets for a very thin and flexible control panel or display that may be simply affixed to an outer surface of any structure.

Subsequent to quality assurance electrical testing, one of two types of environmental barriers may be employed. In the first case, the flexible control panel is placed in a blow molding system where a thin, conformal environmental seal is made over the entire panel with the exception being an electrical access area. In the second case, for rigid clear substrates like Lucite, blow molding is not appropriate, so a front and back environmental seal should be provided, where the seal may be for the panel substrate (including the microLEDs) rather than for the printed material. If multiple layers are used in the control panel, any seal should seal the edges.

FIG. 20A illustrates the user-facing side of a transparent substrate 124 containing an area 126 where the control electronics (e.g., capacitive touch sensors) are printed along with any graphics to be backlit. In another embodiment, the control panel face may be an opaque layer, and the icons may be cut out to form light passing areas. One can also provide various colors in the cut out areas.

FIG. 20B illustrates the back side of the substrate 124, which comprises a microLED light sheet area 127 that is directly printed on the back side of the substrate 124 (as shown in FIGS. 1 and 2) or laminated on the back side of the substrate 124. The pattern of the LEDs may correspond to the printed graphics on the front side of the substrate 124, or the LEDs may be addressed to coincide with the printed graphics. The resulting substrate 124 may be an illuminated touch pad with an array of capacitive touch sensors and icons (e.g., numbers) printed over the array of touch sensors. Additional electronics, either printed on the substrate 124 or external to the substrate 124, interpret the change in capacitance of the touch sensors to determine the location touched and equate the location to a function to be carried out. The thin and flexible backlit control panel may be affixed to any surface and substitute for any common control panel, such as for ATM machines, equipment controls, etc.

In one embodiment, the control panel uses through vias for making an electrical connection between the circuitry on the front of the control panel and a power source and/or to the microLED sheet. Switches formed on the front surface of the control panel may be capacitive switches or piezoelectric types where a touch pressure generates a detected voltage. It is also possible to print sliders and similar complex controls.

### Methods for the Use of Printed Microleds on Clothing—(NTH-LIGT-1015-0211)

The clothing and fashion industry is rapidly approaching a new era in wearable “tech.” With the aid of the printed microLEDs, described with respect to FIGS. 1 and 2, designers of apparel and clothing will be able to enhance the user experience by integrating light into clothing in a unique and distinct way specific to this technology.

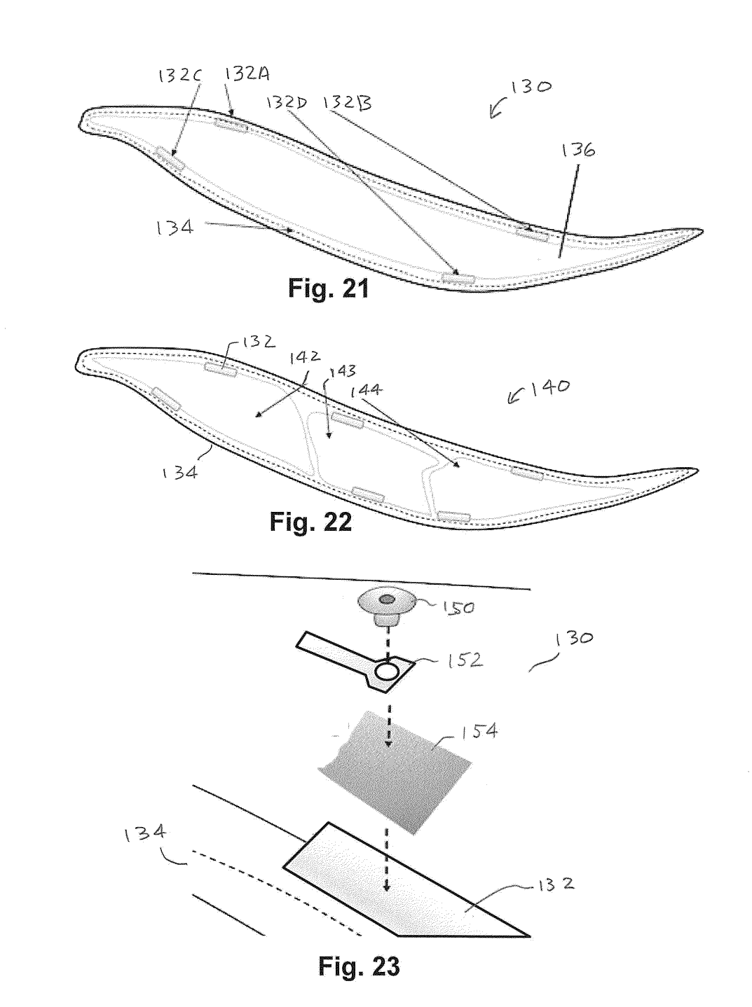

There are several methods of designing a microLED light sheet and integrating it into clothing and apparel. These include but are not limited to the methods shown in FIGS. 21-24.

FIG. 21 illustrates a flat, flexible, shaped microLED light sheet 130 that is particularly suitable for attaching to an article of clothing. The light sheet 130 emits light bidirectionally and has a curved profile (like an S shape) with conductive landing pads 132A-132D (e.g., a transparent conductor or metal) and a sewing boarder 134. The portion 136 contains the printed microLEDs that emit the bidirectional light. The LED light sheet of FIGS. 1 and 2 can emit light bidirectionally by forming both anode and cathode electrodes that allow light to be emitted from the respective LED die surface. Alternatively, two overlapping layers of LED dies may be printed that emit light in opposite directions. The appropriate conductive layers sandwiching the printed LED dies are made transparent (e.g., ITO or sintered silver nano-wires) to achieve the bidirectional emission.

The microLED light sheet 130 of FIG. 21 has a reverse-curved shape which emits light from both sides so the designer can flip one sheet 130 over and rotate it 180 degrees, and then overlie its “downward” facing conductive landing pads 132A-132D with the “upward” facing landing pads 132A-132D of an adjacent identical sheet 130 to connect the sheets in parallel to form any size composite light sheet. A rivet, or soldering, or a conductive adhesive may be used to create good contact between the overlying landing pads. There are anode landing pads 132A and 132D and cathode landing pads 132B and 132C along opposite edges of a sheet 130, where the anode landing pads 132A and 132D of the overlapping sheets 130 connect, and the cathode landing pads 132B and 132C of the overlapping sheets 130 connect. An anode landing pad is across from a cathode landing pad so the proper pads line up when an adjacent sheet is flipped over and rotated 180 degrees. The sheets 130 may be positioned side by side and also end to end to create any size overall light sheet.

The curved shape blends the light from multiple sheets 130 together and promotes more natural flexing of the underlying clothing material, in contrast to the sheets 130 being rectangular which would form well-defined weak and strong flex areas. Further, providing many small microLED sheets 130 rather than a single large sheet allows for a decreased radius of bending without any damage to the sheets 130. Further, providing small microLED sheets allows each sheet to be firmly secured to the clothing by sewing around the edges of the sheets.

Using relatively large rectangular sheets is also contemplated and may be appropriate where there is little or no anticipated flexing of the cloth or other substrate material. Other shapes of the bidirectional, flexible microLED light sheet are also suitable for being sewn onto clothing (or other substrates) and interconnected with identical, but flipped over, microLED light sheets. Such shapes include triangles, other types of S shapes, zig-zags, rectangles, hexagons, etc. Each edge that may be adjacent another microLED light sheet that has been flip over has anode and cathode landing pads to connect the adjacent microLED sheets in parallel.

The two anode landing pads 132A and 132D on a single sheet 130 are electrically connected together, and the two cathode landing pads 132B and 132C on a single sheet 130 are electrically connected together, such as by a metal bus, so that low-resistance anode and cathode buses are formed by interconnecting the sheets 130 together. Additional narrow metal buses may be distributed over the microLED light sheet 130 to reduce resistive losses.

The sewing boarder 134 surrounds the sheet 130 and does not include any LED areas, allowing for sewing machine access to attach the sheet(s) 130 to the desired clothing material.

The size of a single sheet 130 may be any size such as having a length of 4 inches and a widest width of 1 inch.

FIG. 22 illustrates another curved bidirectional microLED sheet 140 that has multiple light zones 142, 143, and 144. There are anode and cathode landing pads 132 for each zone. The multiple zones 142-144 allow for addressable control of the LED dies within each zone to drive the light in slow motion fading or blinking patterns. In this example, there are three separate and distinctly controllable zones 142-144. These separate zones can also be driven together to enable the entire lamp to be driven by a single control channel.

There are multiple methods to electrically connect the printed microLED sheets to one another and to the clothing/apparel. One method is illustrated in FIG. 23. This method includes the use of a flared rivet 150 passing through a metal ring terminal 152 atop a light weight copper leaf 154 that is laid as a mechanical buffer and conductivity enhancer onto the printed silver landing pad 132. Some methods to attach the ring terminal 152 to the copper leaf 154 include: 1) soldering; and 2) using a female crimp terminal to slide onto the shaft of the ring terminal 152. The rivet 150 firmly presses overlying landing pads 132 together and simultaneously affixes the microLED sheets 130 to the clothing, in addition to the sewing around the perimeter.

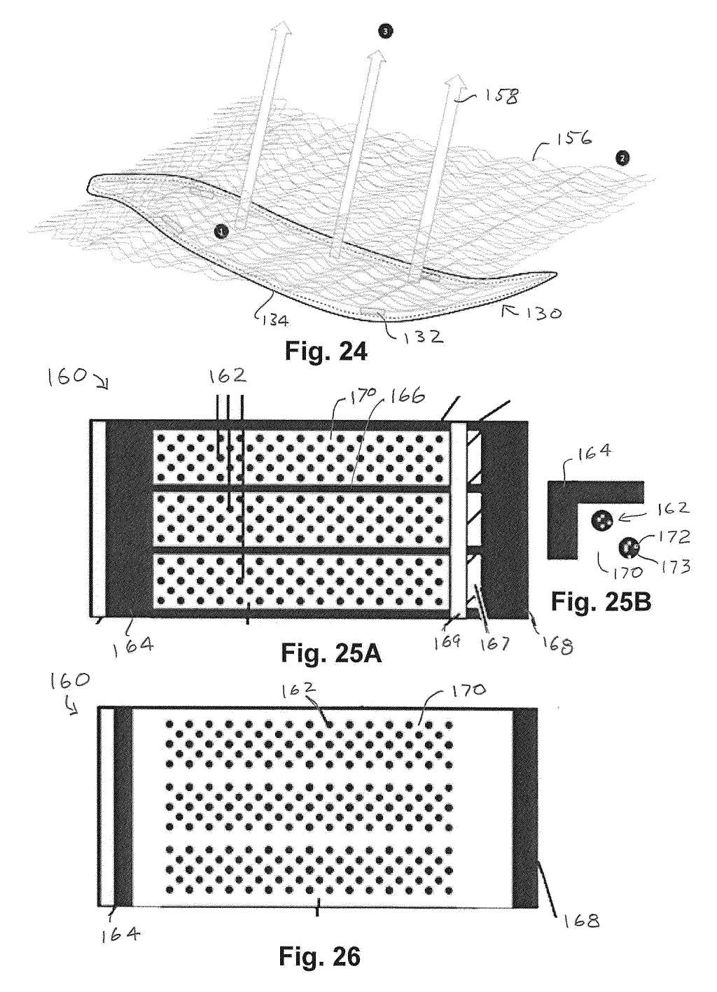

The microLED sheets 130 can be affixed to the outside surface of the clothing or other substrate or affixed to the inner surface of a light-passing material, such as an open weave material, a mesh, or a translucent material. FIG. 24 illustrates a microLED sheet 130 affixed to the inside surface of an open mesh material 156. The sheet 130 would normally be obscured in its off state but is shown superimposed over the material 156 for illustration. In this implementation, the microLED sheet 130 emits light through the mesh material 156 or a transparent material. Light rays 158 are shown.

### Method of Reducing Visibility of Wavelength Conversion Layer—(NTH-LIGT-0413-0144)

A neutral or near-white appearance of lamp surfaces is generally found to be desirable. A phosphor for conversion of blue or UV LED light into white light or a different color is energized by ambient light and emits the converted color.

The native color emitted by a microLED sheet available from the assignee is nearly monochromatic with a peak emission typically between 400 nm and 530 nm, which ranges from violet to green. To meet the requirements of the widest range of possible applications, a color conversion layer on the surface of the lamp must be included to capture and convert some or all of the lamp's native microLED light emission to a desired color or range of colors. As an example, YAG phosphor may be used to convert the native blue light of a microLED to a broad-spectrum white light of an appropriate color temperature. Unfortunately, the YAG phosphor is bright yellow and fluoresces under normal room and outdoor lighting conditions when the micro-LED lamp is turned off. Many people find the yellow color of the phosphor aesthetically unappealing.

One technique that has been commonly employed in traditional LED lamp designs using large LED dies (usually 0.25 mm and larger in diameter) is to hide the LEDs and their color-converting yellow YAG phosphor behind a light diffusing plate. The diffuser plate is placed within the lamp between an observer and the LEDs, usually at some distance from the LEDs. In the case of an LED light bulb, the diffusing plate is the plastic bulb several inches away from the LED light source. The diffuser plate mixes the LED light when the lamp is on and, when the lamp is off, it hides LED light source. With the lamp powered off, the diffuser plate allows light into the lamp, which in turn energizes exposed YAG phosphor within the lamp. The yellow phosphor light mixes with room light scattered directly back in by the diffuser plate, diluting and hiding the colors and patterns of the structures within the lamp housing.

Although diffuser plates can also be used with printed microLED lamps to perform the functions just described, this lamp design strategy compromises the key advantages printed microLED lamps have over traditional lighting sources, such as exceptional thinness and flexibility. Worse yet, the introduction of a diffuser plate significantly reduces the efficiency of both traditional LED and printed microLED lighting systems. Thus, there is a need for a technique to hide the phosphor color without reducing the lamp efficiency.

A method of minimizing the visibility of exposed color conversion phosphor over a printed microLED sheet is described below.

YAG is the typical phosphor used to produce polychromatic light from monochromatic blue light sources such as GaN LEDs. This phosphor is fluorescent yellow when illuminated by natural or artificial white light, which must by definition contain some blue light. The visible blue light, near UV, and UV components present in the ambient white light stimulate the phosphor and cause it to reemit the absorbed light stokes-shifted to frequencies to which the human eye is more sensitive. This behavior is referred to as fluorescing. This stokes-shifted light combines with the red and green components of the ambient light that the phosphor reflects, tricking the eye into perceiving internal luminance within the phosphor by emitting more red and green light (making yellow) than should be present if the source of the red and green reflected light was only from the ambient illumination.

The perceived brightness of YAG phosphor and other types of phosphors that convert blue light to polychromatic white light is the key to developing a technique to greatly diminish the prominence of the phosphor. One well-known oddity of the human visual system comparing colors specified using an HSB color space (hue-saturation-brightness) is that the eye has high planar resolution in hue and brightness, but fairly low planar resolution in saturation, especially in colors such as yellow. In addition, humans perceive pure yellows to have low levels of saturation compared to all other hues. These two behaviors together can be taken advantage of by printing the yellow YAG and a light-neutral background color in a pattern designed in such a way that the phosphor's perceived intense yellow color is greatly diminished.

For example, if moderately high frequency regular patterns of yellow dots (low perceived saturation) is printed on a bright white background layer (zero saturation), the yellow pattern readily blends with the white in the human visual system, producing a perception of a slightly off white surface, which may even be more aesthetically pleasing than pure white. Even a regular pattern of fairly large dots of 2 to 3 mm in diameter spaced 2 to 3 mm apart will blend into a nearly uniform off-white appearance when viewed from less than 3 feet. This viewing distance is conveniently typical of an object being examined while held in the hand. At greater distances, such a fairly low frequency pattern is even more strongly blended by the eye and perceived to be quite uniform in color. Such a lamp is illustrated in FIGS. 25A and 25B. As a general guide, the spacing between dots should be approximately the same or larger than the width of each dot so that the overall area between the dots is greater than the dot area.

For a lamp that is approximately 1 m², there may be about 30,000 dots, assuming the dots have a width of 3 mm and there is a 3 mm spacing between the dots. In one embodiment, the dots are round, and the total area between the dots is greater than twice the area of the dots.

This white or near white neutral tone mask surrounding the phosphor dots, as described above, may be applied as an ink or as a separate opaque laminate sheet or simply as a rigid frame mask over the lamp. If the mask is applied as ink, it is a simple matter to apply the pattern and register it to the phosphor and microLED pattern using a wide variety of well-known printing techniques. If the mask is applied to the lamp surface as an opaque neutral tone laminate mask, or a rigid opaque neutral tone frame mask is used, the laminate or frame may have windows that are aligned with the phosphor and microLED dots in the lamp. The windows may be either actual openings or made of a transparent material.

The lamp 160 of FIGS. 25A and 25B is similar in some respects to the lamp shown in FIG. 2 but shows many more LED dies, and the LEDs are printed only in certain areas. The LED dies are printed in dot-shaped areas 162, and dots of phosphor are printed directly over the areas 162. Two conductive layers sandwich all the LED dies in all the areas 162 so they are all connected in parallel. The top conductive layer is transparent. A top metal bus bar 164 is connected to a positive voltage, assuming a top anode connection to the LED dies, and thin metal runners 166 extend across the transparent conductive layer to distribute current to the LED dies. The bottom conductive layer 167 (which may be transparent or a reflective metal layer) is also shown and is connected to another metal bus bar 168, coupled to a negative cathode voltage, such as ground. A dielectric material 169 provides electrical insulation.

Regions around the dots of phosphor and dots of microLEDs ink are covered with a white or nearly white reflective layer 170. A magnified area in FIG. 25B shows each dot area 162 containing several microLEDs 172 (from a cured LED ink dot) underlying a like sized dot of phosphor 173. Different dot areas 162 may contain different numbers of microLEDs due to the random distribution of the microLEDs in the LED ink. The rest of the lamp surface, including unattractive electrical power buses, may also be hidden with the same white reflective layer 170, leaving only the electrical contacts at the ends of the lamp exposed as can be seen in FIG. 25A. The printing pattern of the white reflective layer 170 (e.g., a white paint) is a negative of the printing pattern of the LED ink and phosphor ink. The phosphor ink comprises phosphor particles in a curable solution. Preferably, the white area surrounding each dot area 162 is greater than the yellow dot area. The larger the ratio of white to yellow areas, the more the lamp appears white.

Typically, the phosphor dots are designed to allow some of the blue LED light to pass through so as to combine the blue and yellow light to create white light. However, in some cases it may be desirable to make the phosphor dots slightly smaller than the LED dots to increase the percentage of blue light in the light output or if the phosphor dots do not allow blue light to pass through.

FIG. 26 illustrates the lamp 160 of FIG. 25A but without the metal runners 166 and certain other detail to show that the light emitting dot-shaped areas 162 are located so as not to be later covered by any opaque metal in the final product.

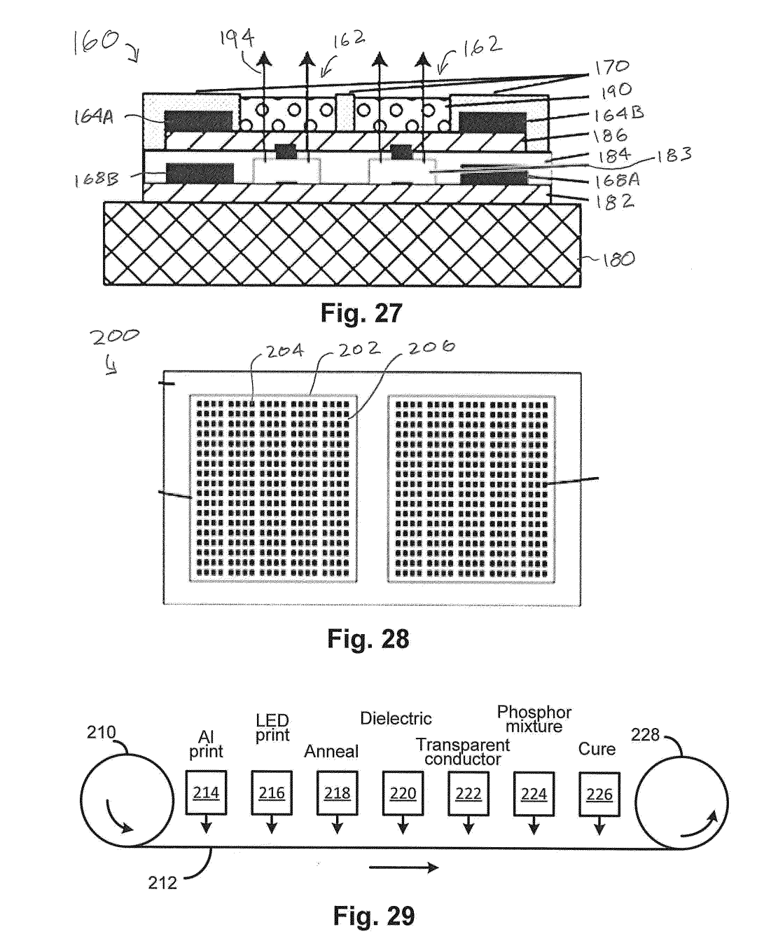

A cross-section of the microLED lamp 160 is shown in FIG. 27. This example is only one of a variety of possible microLED lamp structures in which a phosphor pattern can be combined with a white or near-white neutral tone lamp surface reflector. In FIG. 27, a reflective substrate 180 has a transparent conductive layer 182 printed over it. Metal bus bars 168A and 168B are printed to electrically contact the conductive layer 182. LED dies 183 are printed in the dot-shaped areas 162. The single LED die 183 in each dot area 162 represents a random distribution of microLED dies printed in each dot area 162. A dielectric layer 184 encapsulates the sides of the LED dies 183. A top transparent conductive layer 186 is printed over the LED dies 183 and dielectric layer 184 to contact the anode electrodes of the LED dies 183. Metal bus bars 164A and 164B are printed to electrically contact the conductive layer 186. A phosphor material 190 (phosphor particles in a binder) is printed over each dot of the cured LED ink in the dot areas 162. A white reflective material 170 is then printed on the top surface (or laminated) to cover all areas except the light emitting dot-areas 162. An observer will perceive only a lightly yellow-tinted surface if the phosphor particles are YAG particles. Such a color is referred to as off-white and is aesthetically pleasing. Light rays 194, when the LED dies 183, are shown, which are white if the blue LED light mixed with the yellow YAG light.

Beyond the dot pattern described above, there are many other possible phosphor/white reflector patterns, with the best results achieved when the pattern perimeter-to-area ratio is kept high and line intersections are avoided. Straight or wavy non-crossing thin lines or rows of dots, squares, or diamonds in an array are suitable. Random rotations of the light emitting areas about their dot centers, irregular dot shapes, and innumerable other patterns are possible. Dots with long irregularly shaped perimeters may also improve blending of the yellow phosphor with the white background relative to what can be achieved using dots of the same area with uniform circular shapes. Even dots in the shape of logos might be used to give a viewer a surprise if they choose to very closely examine the lamp surface.

The microLEDs in the lamp are printed in a pattern that exactly matches or is slightly smaller than the phosphor pattern to ensure that the light of every microLEDs in the lamp strikes the conversion phosphor. Although it is generally desirable to convert light from every microLED, it may, in some lamp designs, be desirable for some of the microLEDs to be in areas without phosphor in order to allow their native color to escape the lamp with no conversion of color. For example, blue (400-470 nm wavelength) and red (>600 nm wavelength) microLEDs might both be present in a microLED lamp, and the red microLEDs are printed in areas of the phosphor pattern where no phosphor is present. Depending on lamp construction, the microLEDs may be printed in a layer directly below, or several layers below, the phosphor layer.

A low frequency pattern of yellow phosphor on a white background is quite adequate for use in consumer products for which user impressions during the purchasing process is critical. A slightly off-white lamp has generally been found to be more pleasing to the average consumer then a bright yellow lamp. A consumer will be examining the package at arms-length while reading the package, which is likely the closest they will ever be to the lamp. Installed lamps will have a significantly greater viewing distance. This makes the previously described 2-3 mm dot pattern more than adequate for the task of muting the yellow phosphor color on the surface of a lamp in a consumer product.

Other strategies may also be used in consumer products to reduce the perceived yellow color of a lamp at the time the lamp is being purchased. For example, UV and near-UV absorbing compounds may be incorporated into the clear window in the package through which the product can be viewed. This reduces the fluorescing effect in the yellow phosphor on the lamp inside the package by absorbing some of the radiation that can stimulate the phosphor before it reaches it. Alternatively, the clear window may incorporate a blue fluorescent material that tints the package window slightly blue in order to reduce the intensity of the yellow phosphor. The more UV component present in the ambient store lighting, the brighter the blue emission from the package window to offset and neutralize the yellow emission by the phosphor on the lamp in the package. Yellow and blue are anti-colors, meaning that mixing them in equal parts will produce the perception of a neutral tone.

For commercial lamps, such as overhead lamps, where viewing distances of installed lamps are in general more than several feet, the yellow phosphor dot sizes may be larger. Using a dot pattern similar to the one described previously, but using 4 to 5 mm yellow dots separated by 2 to 3 mm will minimize the perceived yellow color of a commercial lamp viewed at typical ceiling distances. For commercial lamps with larger viewing distances, even lower frequency phosphor patterns may be used. An example can be seen in FIG. 28.

FIG. 28 illustrates a large lamp 200, such as a 2 foot×4 foot troffer for overhead lighting. Two identical light emitting sections 202 of the lamp 200 contain a blue microLED light sheet, having an array of LED dots and YAG phosphor (yellow) dots 204 overlying the LED dots. The area 206 surrounding the phosphor dots 204 is a neutral color to effective mask the yellow color. The dots 204 are shown as square shaped.

To make the blending of the yellow phosphor with the surrounding light background even more effective, it is possible to reduce the intensity of the white used in the surrounding reflective layer to a light gray, in order to better match the perceived brightness of the yellow phosphor. For example, using LAB color space, if the perceived L* (i.e., luminance or brightness) of the white can be matched to the L* of the yellow, the only perceived difference between the two regions will be in saturation where the human eye is least sensitive to tonal differences. In addition, it may be useful for the white or off-white gray ink used to print the light background to include a near-UV fluorescor, sometimes referred to as a brightener, to better match the perceived brightness of the yellow phosphor when viewed under both low and high ambient lighting levels.

Using a non-neutral color for the phosphor pattern surrounding is another possible approach. Hues may be applied in areas around the phosphor that mix with the yellow of the phosphor to produce a more pleasing off-lamp color. This is similar to using a half-tone pattern in a traditional four color process printing to produce a wide range of colors. A color that has a similar brightness and saturation of the phosphor (e.g., YAG), but having the anti-hue of yellow (i.e., blue), may be selected to produce the perception of a near neutral gray lamp surface. Accordingly, with respect to FIGS. 26-28, if the phosphor dot areas and the surrounding areas were made to be about the same size (in area), and the surrounding areas were printed over with the anti-hue of yellow, the perceived overall color would be a neutral color. An anti-color is also referred to as an opposite additive color on a color wheel or a complementary additive color.

A non-diffusing layer may optionally be deposited or laminated over the entire front surface for protection of the phosphor dots. The non-diffusing layer may include optics to direct the light to reduce glare. No diffusing layer is needed to mask the phosphor in the off state, so there is a high efficiency of light extraction from the lamp.

### Method to Form Embodiments Using a Roll-to-roll Printing Process

All the embodiments of LED light sheets and phosphors may be inexpensively printed in a roll-to-roll process under atmospheric conditions. FIG. 29 illustrates a simplified fabrication process for forming wide-area phosphor-converted LED light sheets that emit white light for any application.

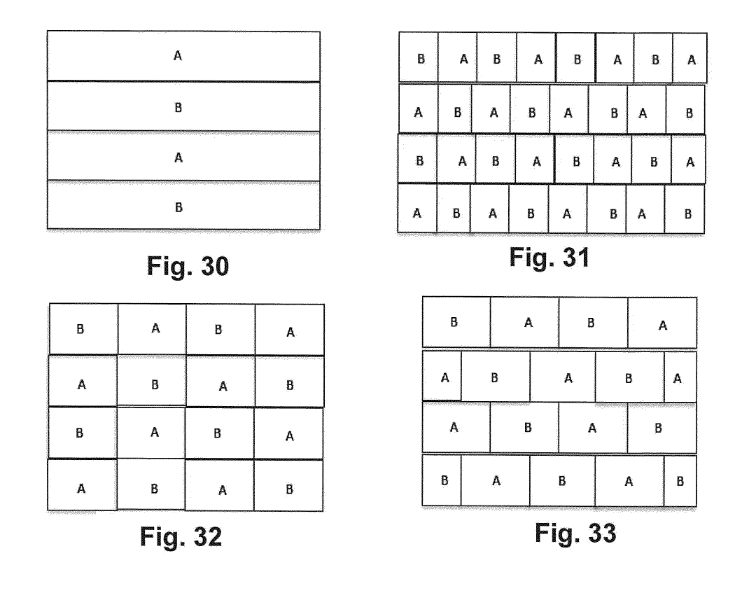

A roll 210 of a thin flexible substrate 212, such as a polymer or aluminum, is provided. The substrate 212 may be moved along the assembly line continuously or intermittently. A single process may be performed on the entire roll before the roll is subjected to the next process. FIG. 30 shows the various general processes that may be performed on the substrate 212, rather than an actual assembly line. For example, the same printing tools may be used to deposit different inks at different stages of the process, rather than a different printing tool being used for each type of ink. So there may not be the various separate stations shown in FIG. 30.

At a first station 214, an aluminum ink is printed over the surface of the substrate to form an aluminum layer.

At a second station 216, the LED dies are printed so that the bottom electrodes of the dies make electrical contact with the aluminum layer.

At a third station 218, the aluminum layer is annealed to fuse the LED dies' bottom electrodes to the aluminum layer.

At a fourth station 220, a dielectric layer is printed over the aluminum layer.

At a fifth station 222, a transparent conductor is printed over the top electrodes of the LED dies to electrically connect groups of the LED dies in parallel. Metal traces may also be printed to reduce the overall resistance of the current paths.

At a sixth station 224, the phosphor mixture is printed over the LED die array. At a seventh station 226, the resulting light sheet layers are cured.

The light sheet is then provided on a take-up roll 228. The light sheets may be separated (cut) from the roll 228 at a later time for use in a particular application.

### A Multiple Wavelength LED Light Fixture for Various Medical Applications (NTH-LIGT-0117)

Different wavelength electromagnetic radiation is useful in medical applications. For example, short wavelength electromagnetic radiation (230-360 nm) is effective in killing bacteria and is often used for sterilization purposes. Wavelengths of 360-404 nm may be obtained with GaN and shorter UV wavelengths with AN LEDs. Wavelengths between the near UV (˜380 nm) and green (˜540 nm for InGaN), are useful for selectively exciting fluorescence of certain proteins and other biological compounds. Wavelengths in the red region of the spectrum (GaP, 620-680 nm) are useful for rendering the color of blood. Wavelengths longer than 650 nm (InGaP and GaAs) are transmitted through many cellular structures, such as, skin and enable one to look through at least thin layers of tissue.

Although conventional light sources are used in all the above applications, in order to achieve wavelength selectivity, one must use either different lamps for the different applications or combinations of lamps or filters to select the desired wavelengths. On the other hand, LEDs afford high intensity efficient light sources with flexibility in wavelength of their output depending on the composition and structure of the LED. LEDs are rapidly finding applications in the medical field and are replacing more traditional light sources, such as, halogen lamps, HID lamps and low pressure discharge lamps, for example for endoscopic procedures.

LED's providing electromagnetic radiation of different wavelength outputs can be optimized for different medical applications including surgery, diagnostic evaluation of tissue, imaging and other procedures.

The purpose of this invention is to provide multiple wavelengths or wavelength tunability in a single fixture. In addition, such LEDs can simultaneously provide conventional lighting either for viewing or imaging.

FIGS. 30-33 illustrate different patterns of LEDs that are useful for supplying different wavelengths of light for different medical applications. The individual LEDs are not shown but form a random distribution of microLEDs by printing. Any density of the LEDs can be achieved. The different sections, labeled A and B, contain different wavelength LEDs, assuming that only a single type of LED is included in a single printable LED ink. Since different types of LEDs typically have different forward voltages, the different sections of LEDs may need to be driven with a different driving voltage to achieve the desired light emission. This may be done with a single power supply using time division multiplexing. Additional types of LEDs, emitting different wavelengths, may also be added to the patterns of FIGS. 30-33, adding more sections distributed among the sections A and B.

LEDs that provide the electromagnetic radiation for each operating mode are located physically adjacent to each other in a pattern such as adjacent stripes (FIG. 30), squares (FIG. 31), rectangles (FIG. 32), mixed shapes (FIG. 33), or any other interspersed arrangement that allows the same power supply to provide current to drive each set of LEDs at different times. The mechanical and optical sections of the light fixture may also be shared.

The LEDs may be printed on a flexible substrate (like in FIG. 1) to form an adhesive patch worn on a patient's skin, or the substrate may be mounted on any other surface. Sensor circuits that sense the light reflected or passing through the patient may also be printed or mounted on the substrate. Data from the sensors may be processed by an external computer.

A standardized array of LEDs of different wavelengths may be provided on a substrate and only a subset of the LEDs may be energized for a particular application, such as for detecting the characteristics of blood, or for sterilizing, etc.

Because the LEDs can be made very small, such as less than 25 micrometers in diameter, they can be printed in any of the above patterns with features less than 100 micrometers in size. Hence up to ten stripes or rectangles or other geometric features, each with different wavelength LEDs, can be printed on a substrate no larger than 1 millimeter in size providing a small, multiple wavelength flexible radiation source that can be easily focused, transmitted through an optical fiber, placed on the tip or edge of a scalpel or hypodermic needle or below a microscope sample, etc.

### A Method and Device for Building a Massively Parallel, Distributed RGB Sensor Based Upon the Retina of the Human Eye (NTH-LIGT-0119)

The human retina can be considered to be a massively parallel set of sensors that work in RGBL* (where L* is brightness) mode. From 60 to 127 million sensors (rods and cones) are packed into an area of less than 12 square centimeters. The acuity and dynamic range of the intact human eye is remarkable and is unmatched by device engineering for a general sensing device.

The below description presents a novel printed device that can be used as a “flies eye” camera. Both very large sized arrays with large numbers of pixels or very small sized arrays with limited numbers of pixels for specific sensors can be printed. No particular sensor frequency is assumed.

Consider an array of photodiodes that is 1 or two orders of magnitude larger in area than the biological example. In this array, we print photodiodes that are sensitive to R, G, or B wavelengths via a Bayer filter array and, possibly, a photodiode that is brightness sensitive only. A Bayer filter is a color filter array (a mosaic) for arranging RGB color filters on a square grid of photosensors. The Bayer filter's particular arrangement of color filters is used in most single-chip digital image sensors used in digital cameras, camcorders, and scanners to create a color image. The Z orientation of the photodiodes is not really too important as only one orientation needs to be used. Array completion need not be absolutely perfect as subsequent processing will adjust for missing micro pixels.

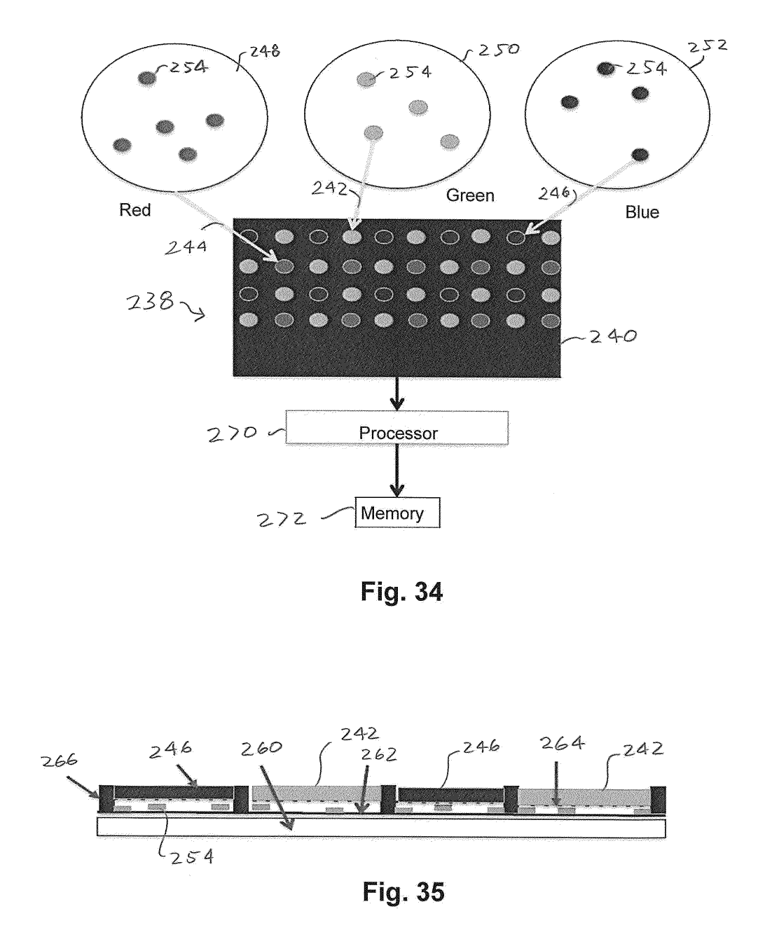

FIG. 34 illustrates a light sensor array 238 along with a block diagram of the support circuitry. FIG. 34 shows the filter color array structure for the Bayer array filter 240, where green light filters 242, red light filters 244, and blue light filters 246 are distributed over the Bayer array filter 240. Such an array has been commonly used in CCDs (see U.S. Pat. No. 3,971,065, issued in 1976).

Below each of the filters 242, 244, and 246 is a printed dot (a pixel) of microscopic photodiodes forming a sensor. The magnified dots 248, 250, and 252 show the random distribution of the printed photodiodes 254 of representative dots for the red, green and blue pixels, respectively. If the photodiodes 254 can detect a wide range of wavelengths, the same photodiode can be printed for each color pixel. As seen, each pixel in the sensor is really an array of arrays of photodiodes 254. So, very large composite arrays can be assembled.

The array of pixels does not need to be co-planar or contiguous. Thus, a single frame can show a perspective from several orientations. Each pixel consists of N photodiode elements. Such elements are connected in parallel by being sandwiched between printed conductive layers and need not be of a specific number.

FIG. 35 is a cross-sectional view of a portion of the light sensor array across four pixels. FIG. 35 illustrates a substrate 260, printed photodiodes 254 over a conductive layer 262, a transparent conductive layer 264, opaque pixel walls 266 to prevent cross-talk, blue light filters 246, and green light filters 242.

A processor 270 (FIG. 34) scans the different pixels (photodiodes in each dot) and combines the detected signals (for the various colors) using a convolution algorithm. The signal output from such an array of pixels is weighted in software after calibration for upper and lower limit variance and for range variance. So, when shown a monochromatic test target, the response surface is flat and remains flat (at a different gain) as the test target is changed throughout a given range. Therefore, the signal from the macro array is consistent throughout the visible or non-visible range. The processed data is stored in a memory 272.

The sensor can be used for any suitable purpose to detect images, colors, etc.

Note that the measured signal (as opposed to the calibration signal) is derived from the pass through of the Bayer filter. The resolution of the device is dependent upon the number of pixels, the area that the device “views,” and the wavelength (“narrowness”) of the filter material. Further, the construction of the array can be such that a layer is printed to make light opening a “pin hole” device so no focal, length is required.

In all embodiments, all LED dies may be printed to be oriented in the same direction (e.g., anodes up) and driven with a DC voltage. Alternatively, the LED dies may be randomly oriented (about 50% each orientation) or be specifically designed to have different percentages of each orientation and driven with an AC voltage to illuminate different LEDs with the different voltage polarities.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

What is claimed is:

1. A light emitting structure comprising:
a plurality of light emitting diode (LED) dies printed as an array of first dots on a substrate, where each dot includes at least one LED die;
a phosphor deposited as second dots covering at least a portion of the first dots, the second dots having a first color of phosphor-emitted light under ambient light when the LED dies are in an off state; and
first areas between the second dots being of a neutral color or a complementary color, relative to the first color, to reduce a perception of the first color second dots by a human observer.

2. The structure of claim 1 wherein the second dots comprise one of round dots or dots with straight edges.

3. The structure of claim 1 wherein the second dots have a width of 3 mm or less.

4. The structure of claim 1 wherein a combined area of the first areas is greater than a combined area of the second dots.

5. The structure of claim 1 wherein a combined area of the first areas is at least twice as great as a combined area of the second dots.

6. The structure of claim 1 wherein the first areas are white.

7. The structure of claim 1 wherein the first color comprises yellow and the first areas comprises blue.

8. The structure of claim 1 wherein the second dots are larger than the first dots.

9. The structure of claim 1 wherein the second dots are smaller than the first dots.

10. The structure of claim 1 wherein light from the LED dies combines with light emitted by the phosphor to generate white light.

11. The structure of claim 1 wherein the structure comprises an overhead lamp for general illumination.

12. The structure of claim 1 wherein the number of second dots in the structure exceeds 1000.

13. The structure of claim 1 wherein the LED dies are microscopic LED dies printed using an LED ink, and there are a random number of LED dies within each of the first dots.

14. The structure of claim 1 wherein there is no diffusing layer between the second dots and an observer.

15. The structure of claim 1 wherein the first dots and second dots are printed in straight rows and columns.

16. The structure of claim 1 wherein the first dots and second dots are printed in non-straight lines.
